(19) United States
(12) Patent Application Publication
(10) Pub. No.: US 2016/0276491 A1
(43) Pub. Date: Sep. 22, 2016

(54) Thin Film Transistor, Array Substrate and Display Device

(71) Applicant: BOE TECHNOLOGY GROUP CO., LTD., Beijing (CN)

(72) Inventor: Wenwen SUN, Beijing (CN)

(21) Appl. No.: 14/761,862

(22) PCT Filed: Jan. 7, 2015
(86) PCT No.: PCT/CN2015/070279

§ 371 Date: Jul. 17, 2015

(30) Foreign Application Priority Data
Sep. 25, 2014 (CN) 201410498497.4

(51) Int. Cl. H01L 29/786; H01L 27/12; H01L 29/423

(52) U.S. Cl. CPC H01L 29/78636; H01L 29/42384; H01L 27/1214

(57) ABSTRACT

The present invention discloses a thin film transistor (TFT), an array substrate comprising the TFT and a display device comprising the array substrate. The TFT comprises a gate, a source, a drain, and a semiconductor layer and an insulating layer which are both provided between the source, the drain and the gate, the insulating layer is made of inorganic insulating material, a modifying layer is provided between the insulating layer and the semiconductor layer and in an area corresponding to the insulating layer, and the modifying layer is made of organic aliphatic silane material. The surface of the insulating layer of the TFT is smoother with a state of less or substantially no surface defects.

### FIELD OF THE INVENTION

The present invention relates to the field of display technology, and particularly to a thin film transistor, an array substrate and a display device.

### BACKGROUND OF THE INVENTION

With the development of information technology, people also set higher and higher requirements for the screen display quality of the electronic display device, correspondingly set higher requirements for the array substrate as a core component of the display device, and require the array substrate to have higher performance parameters.

The array substrate includes a plurality of thin film transistors (TFTs) which are provided in a matrix, and the display of an image is realized through the switch control of the TFTs. At present, the structure of a TFT includes a gate, a source, a drain, and a semiconductor layer and an insulating layer which are both provided between the gate and the source/drain. The insulating layer is generally formed by using an inorganic insulation material to have a better insulation effect. However, the inorganic insulating material has stronger hydrophilicity, and the surface is not smooth, so it is easy to produce a surface defect state, resulting in a reduced number of effective electrons in the process of transmitting electrons in the TFT, a low migration rate and on/off ratio characteristic of the TFT, and a poor performance of the TFT.

Thus, it becomes a technical problem to be solved urgently at present to design a TFT with a state of less or substantially no surface defects and with a higher migration rate and on/off ratio characteristic.

### SUMMARY OF THE INVENTION

In order to solve the above-mentioned technical problem existing in the prior art, the embodiments of the present invention provide a TFT, an array substrate comprising the TFT and a display device comprising the array substrate, the surface of the insulating layer of the TFT is smoother and has a state of less or substantially no surface defects, so that the TFT has a relatively high migration rate and on/off ratio characteristic, and has a better performance.

The embodiments of the present invention provide a TFT comprising a gate, a source, a drain, and a semiconductor layer and an insulating layer which are both provided between the source, the drain and the gate, wherein the insulating layer includes comprises an inorganic insulating material, a modifying layer is provided between the insulating layer and the semiconductor layer, and in an area corresponding to the insulating layer, and the modifying layer includes comprises an organic aliphatic silane material.

The insulating layer may comprise material containing silicon atoms, and the modifying layer may comprise silane coupling agent containing chlorine atoms.

The insulating layer may include a monolayer or laminated structure formed by silicon dioxide or silicon nitride, and the modifying layer may include a thin film structure of tetradecyl trichlorosilane, hexadecyl trichlorosilane, octadecyl trichlorosilane or eicosyl trichlorosilane.

The relative dielectric constant of the material of the modifying layer may be in the range from 2.5 to 3.5.

The thickness of the modifying layer may be in the range from 50 nm to 300 nm.

The modifying layer may be formed as a film by way of coating.

In the TFT, the gate, the insulating layer, the modifying layer, the semiconductor layer, and the source and the drain which are both provided in the same layer may be provided successively from the bottom up.

Alternatively, the TFT may be provided successively from the bottom up with the source and the drain which are both provided in the same layer, the semiconductor layer, the modifying layer, the insulating layer and the gate.

The insulating layer may be formed as a film by using plasma enhanced chemical vapor deposition, the semiconductor layer may be formed as a film by using plasma enhanced chemical vapor deposition, the gate may be formed by using magnetron sputtering, and the source and the drain may be formed as films by using magnetron sputtering deposition.

The embodiment of the present invention provides an array substrate comprising the above-mentioned TFT.

The embodiment of the present invention provides a display device comprising the above-mentioned array substrate.

A modifying layer is used in the TFT according to the embodiments of the present invention, such a TFT, in comparison with the TFT not provided with the modifying layer, has a higher migration rate, better on current and off current characteristics, and thus has a better performance.

Accordingly, the array substrate comprising the TFT also has a better control effect.

Accordingly, the display device comprising the array substrate also has a better display effect.

### BRIEF DESCRIPTION OF THE DRAWINGS

FIG. 1 is a structural schematic diagram of a TFT according to an embodiment of the present invention.

FIG. 2 is a schematic diagram illustrating that chemically modifying an insulating layer by using material of eicosyl trichlorosilane.

### DETAILED DESCRIPTION OF THE EMBODIMENTS

To make the person skilled in the art better understand the technical solution of the present invention, the TFT, array substrate and display device which are provided by the present invention are further described below in detail in conjunction with the accompanying drawings and the specific embodiments.

The main technical concept of the present invention is that, for the problem in which the insulating layer made of inorganic insulating material has relatively strong hydrophilicity and is easy to produce surface defect state due to unsmooth surface, the characteristic that the surface of an organic material layer is smoother than the surface of an inorganic insulating material layer (such as the layer made of silicon dioxide SiO₂ or silicon nitride SiNx) is utilized, and organic aliphatic silane with lower relative dielectric constant is applied to the surface of the insulating layer made of inorganic insulation material as a modifying layer, so as to make the insulating layer smoother, and the nature that the organic aliphatic silane itself, which forms the modifying layer, can react chemically with the dangling bonds at the surface of the insulating layer made of inorganic insulating material is used to reduce the electron capture of the surface defect state of the insulating layer, increase the number of effective electrons, and realize the high mobility rate and on/off ratio characteristic of the TFT.

### First Embodiment

This embodiment provides a TFT which includes a gate, a source, a drain, and a semiconductor layer and an insulating layer which are both provided between the gate and the source and drain, the insulating layer is formed by using an inorganic insulating material. In addition, a modifying layer is provided between the insulating layer and the semiconductor layer and in an area corresponding to the insulating layer, and the modifying layer is formed by using organic aliphatic silane material.

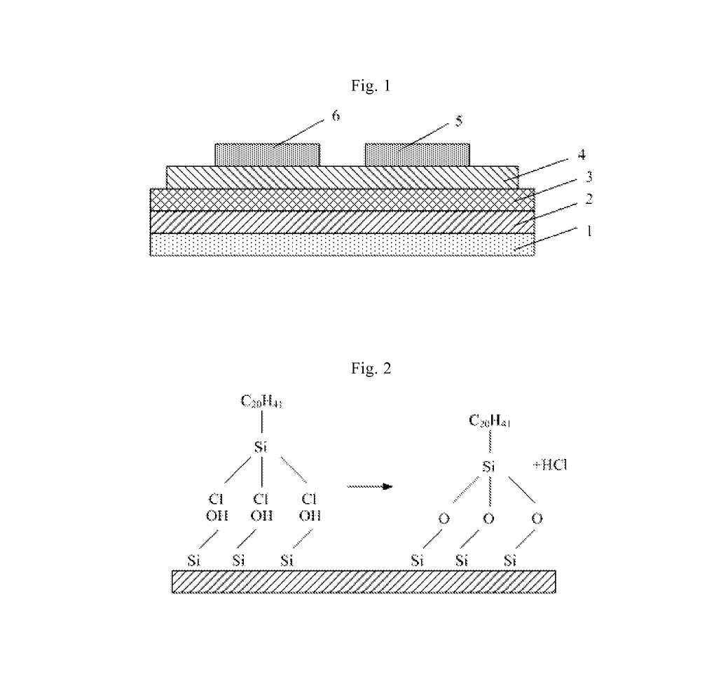

FIG. 1 is a structural schematic diagram of a TFT in this embodiment, the TFT is provided successively from the bottom up with a gate 1, an insulating layer 2, a modifying layer 3, a semiconductor layer 4, a source 5 and a drain 6 which are both provided in the same layer. The insulating layer 2 comprises material containing silicon atoms, and the modifying layer 3 comprises silane coupling agent containing chlorine atoms.

The silane coupling agent is a class of organic silicon compound in whose molecule two groups with different chemical properties are contained simultaneously, and the classic product thereof may be represented by using a general formula YSiX₃. In the formula, the Y is a non-hydrolysable group, comprising the alkenyl group (vinyl group mainly), and the end has the alkyl groups of Cl, NH₂, SH, epoxy, N₃, (meth) acrylate acyloxy group, isocyanate group and other functional groups, namely carbon functional groups; and the X is a hydrolysable group, comprising Cl, OMe, OEt, OC₂H₄OCH₃, OSiMe₃, OAc, and the like. Due to such a special structure, in the molecule thereof, the reactive group capable of being combined chemically with inorganic material (such as glass, silica sand, metal and the like) and the reactive group capable of being combined chemically with organic material (such as synthetic resin and the like) are included simultaneously, so that the compound can be used for surface treatment. In this embodiment, the silane coupling agent containing chlorine atoms has a general formula of H(CH₂)ₙSiCl₃, where n=7, 8, 9 or 10.

In this embodiment, considering the improving effect on the performance of the TFT, the relative dielectric constant of the material forming the modifying layer 3 may be in the range from 2.5 to 3, and since the relative dielectric constant of the material is less than that of the inorganic insulating material, the power consumption of the TFT, the array substrate and display device which include the TFT can be reduced.

Specifically, the insulating layer 2 may be of a monolayer or laminated structure formed by using silicon dioxide (SiO₂) or silicon nitride (SiNₓ), and the modifying layer 3 formed by using the silane coupling agent containing chlorine atoms may be of a thin film structure formed by using tetradecyl trichlorosilane (molecular formula C₁₄H₂₉SiCl₃), hexadecyl trichlorosilane (molecular formula C₁₆H₃₃SiCl₃), octadecyl trichlorosilane (molecular formula C₁₈H₃₇SiCl₃) or eicosyl trichlorosilane (molecular formula C₂₀H₄₁SiCl₃).

Normally, the structures of various layers of the TFT are formed by patterning processes. It should be understood that in the present invention, the patterning process may include only a photolithography process, or include a photolithography process and an etching step, and also may include printing, inkjet printing and other processes for forming a predetermined pattern. The photolithography process refers to processes which include film formation, exposure, development and the like and by which a pattern is formed by using the photoresist, mask plate, exposure machine and the like. A corresponding pattering process may be selected according to the structure as formed in the present invention.

Specifically, in the method for fabricating the TFT in this embodiment, a pattern comprising a gate 1 is first formed through a patterning process, and a pattern comprising an insulating layer 2 made of inorganic insulating material is formed on the gate 1 through a patterning process.

Then, a modifying layer 3 made of organic aliphatic silane material is formed on the area corresponding to the insulating layer 2 through a patterning process, and the modification of organic solvent is performed on the insulating layer 2 through the modifying layer 3. FIG. 2 is a schematic diagram illustrating that chemically modifying the insulating layer 2 by forming the modifying layer 3 by using the material of eicosyl trichlorosilane. The material of eicosyl trichlorosilane itself which forms the modifying layer 3 may react chemically with the dangling bonds of silicon dioxide or silicon nitride at the surface of the insulating layer 2 made of inorganic insulating material, namely the hydroxyl groups of the material in the insulating layer 2 reacts chemically with the chlorine atoms of the material in the modifying layer 3 to form a product as shown in FIG. 2.

Then, a semiconductor layer 4 is formed above the modified insulating layer 2 (namely, on the modifying layer 3) through a patterning process, and a source 5 and a drain 6 are further formed on the semiconductor layer 4 through a patterning process.

In the process of fabricating the TFT of this embodiment, the modifying layer 3 is formed as a film by way of coating (such as spin coating), and the thickness of the modifying layer 3 is in the range from 50 nm to 300 nm, so as to achieve a better modifying effect on the insulating layer 2. In addition, the insulating layer 2 is formed as a film by using plasma enhanced chemical vapor deposition, and the thickness of the insulating layer 2 is in the range from 1000 Å to 3000 Å. The semiconductor layer 4 is formed as a film by using plasma enhanced chemical vapor deposition, and the thickness of the semiconductor layer 4 is in the range from 1000 Å to 4000 Å. The gate 1 is formed as a film by using magnetron sputtering, and the thickness of the gate 1 is in the range from 2000 Å to 4000 Å. The source 5 and drain 6 are formed as films by using magnetron sputtering deposition, and the thickness of the source 5 and drain 6 is in the range from 3000 Å to 4000 Å.

In the above-mentioned TFT, since the surface modification treatment is carried out on the insulating layer 2 made of inorganic insulating material by using an organic aliphatic silane material, the surface of the insulating layer 2 of the TFT is smoother and has less surface defect state or substantially no surface defect state, so that the TFT has a higher migration rate and on/off ratio characteristic, and thus the performance of TFT devices is improved. The above-mentioned process for fabricating a TFT is simple, and the TFT has a higher performance and better characteristic parameters in comparison with the existing TFT.

Shown below in Table 1 is a comparison in performance between the TFT that is not provided with the modifying layer in the prior art and the TFT provided with the modifying layer in this embodiment.

TABLE 1

| Layer structure | Migration rate μ(cm²/Vs) | Current Ion/Ioff |
|---|---|---|
| insulating layer | 0.24 | 2.5 × 10⁶ |
| insulating layer/ | 0.52 | 9.0 × 10⁶ |
| modifying layer | | |

It can be seen from Table 1 that in comparison with the TFT that is not provided with the modifying layer, the TFT provided with the modifying layer has a higher migration rate, better on current and off current characteristics, and thus has a better performance.

### Second Embodiment

This embodiment provides a TFT, wherein the relative positions of the gate, source and drain are different in comparison with that in the first embodiment.

That is to say, the TFT in the first embodiment is a bottom gate type one, whereas the TFT in this embodiment is a top gate type one. The TFT of this embodiment is provided successively from the bottom up with a source and a drain which are both provided in the same layer, a semiconductor layer, a modifying layer, an insulating layer, and a gate.

The structures of any other layers of the TFT in this embodiment is the same as the structures of the corresponding layers of the TFT in the first embodiment, and the method for fabricating each layer is the same as the method for fabricating the corresponding layer in the first embodiment, which are no longer described here in detail.

The TFT in this embodiment has a higher migration rate, better on current and off current characteristics, and thus has a better performance.

### Third Embodiment

This embodiment provides an array substrate, which includes a TFT in the first or second embodiment.

The array substrate includes a plurality of TFTs which are provided in a matrix, and the display of an image is realized through the switch control of the TFT. The array substrate is applicable to a liquid crystal display (LCD) or an organic light-emitting diode (OLED).

Since the TFT in the array substrate has a higher migration rate, better on current and off current characteristics, the TFT has a better performance, and accordingly the array substrate also has a better control effect.

### Fourth Embodiment

This embodiment provides a display device, which includes an array substrate in the third Embodiment.

The display device may be a liquid crystal panel, an electronic paper, an OLED panel, a mobile phone, a tablet computer, a TV set, a display, a laptop, a digital photo frame, a navigator or any product or component with a display function.

Since the array substrate utilized by the display device has a better control effect, accordingly the display device also has a better display effect.

It should be understood that the above-mentioned embodiments are only exemplary embodiments for illustrating the principle of the present invention, but the present invention is not limited thereto. Various variations and improvements can be made by the person skilled in the art without departing from the spirit and essence of the present invention, and these variations and improvements should also be considered to be within the protection scope of the present invention.

1-11. (canceled)

12. A thin film transistor, comprising a gate, a source, a drain, and a semiconductor layer and an insulating layer which are both provided between the gate and the source and drain, wherein
the insulating layer comprises inorganic insulating material, a modifying layer is provided between the insulating layer and the semiconductor layer and in an area corresponding to the insulating layer, and the modifying layer comprises organic aliphatic silane material.

13. The thin film transistor of claim 12, wherein the insulating layer comprises material containing silicon atoms, and the modifying layer comprises silane coupling agent containing chlorine atoms.

14. The thin film transistor of claim 13, wherein the insulating layer comprises a monolayer or laminated structure of silicon dioxide or silicon nitride, and the modifying layer comprises a thin film structure of tetradecyl trichlorosilane, hexadecyl trichlorosilane, octadecyl trichlorosilane or eicosyl trichlorosilane.

15. The thin film transistor of claim 12, wherein a relative dielectric constant of the material of the modifying layer ranges from 2.5 to 3.5.

16. The thin film transistor of claim 12, wherein a thickness of the modifying layer ranges from 50 nm to 300 nm.

17. The thin film transistor of claim 12, wherein the modifying layer is formed as a film by way of coating.

18. The thin film transistor of claim 12, wherein the thin film transistor is provided successively from the bottom up with the gate, the insulating layer, the modifying layer, the semiconductor layer, and the source and the drain which are both provided in the same layer.

19. The thin film transistor of claim 12, wherein the thin film transistor is provided successively from the bottom up with the source and the drain which are both provided in the same layer, the semiconductor layer, the modifying layer, the insulating layer, and the gate.

20. The thin film transistor of claim 12, wherein the insulating layer is formed as a film by using plasma enhanced chemical vapor deposition, the semiconductor layer is formed as a film by using plasma enhanced chemical vapor deposition, the gate is formed by using magnetron sputtering, and the source and the drain are formed as films by using magnetron sputtering deposition.

21. An array substrate, comprising a thin film transistor, the thin film transistor comprising a gate, a source, a drain, and a semiconductor layer and an insulating layer which are both provided between the gate and the source and drain, wherein
the insulating layer comprises inorganic insulating material, a modifying layer is provided between the insulating layer and the semiconductor layer and in an area corresponding to the insulating layer, and the modifying layer comprises organic aliphatic silane material.

22. The array substrate of claim 21, wherein the insulating layer comprises material containing silicon atoms, and the modifying layer comprises silane coupling agent containing chlorine atoms.

23. The array substrate of claim 22, wherein the insulating layer comprises a monolayer or laminated structure of silicon dioxide or silicon nitride, and the modifying layer comprises a thin film structure of tetradecyl trichlorosilane, hexadecyl trichlorosilane, octadecyl trichlorosilane or eicosyl trichlorosilane.

24. The array substrate of claim 21, wherein a relative dielectric constant of the material of the modifying layer ranges from 2.5 to 3.5.

25. The array substrate of claim 21, wherein a thickness of the modifying layer ranges from 50 nm to 300 nm.

26. The array substrate of claim 21, wherein the modifying layer is formed as a film by way of coating.

27. The array substrate of claim 21, wherein the thin film transistor is provided successively from the bottom up with the gate, the insulating layer, the modifying layer, the semiconductor layer, and the source and the drain which are both provided in the same layer.

28. The array substrate of claim 21, wherein the thin film transistor is provided successively from the bottom up with the source and the drain which are both provided in the same layer, the semiconductor layer, the modifying layer, the insulating layer, and the gate.

29. The array substrate of claim 21, wherein the insulating layer is formed as a film by using plasma enhanced chemical vapor deposition, the semiconductor layer is formed as a film by using plasma enhanced chemical vapor deposition, the gate is formed by using magnetron sputtering, and the source and the drain are formed as films by using magnetron sputtering deposition.

30. A display device, comprising the array substrate of claim 21.
